(19) United States
(12) Patent Application Publication
(10) Pub. No.: US 2025/0185465 A1
(43) Pub. Date: Jun. 5, 2025

(54) DISPLAY PANEL, DISPLAY APPARATUS, AND METHOD FOR MANUFACTURING DISPLAY PANEL

(71) Applicants: Hefei Visionox Technology Co., Ltd., Hefei (CN); KunShan Go-Visionox Opto-Electronics Co., Ltd, Kunshan (CN)

(72) Inventors: Zhiwei ZHOU, Hefei (CN); Jinfang ZHANG, Hefei (CN); Manli CHEN, Hefei (CN); Lu ZHANG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/739,570

(22) Filed: Jun. 11, 2024

(30) Foreign Application Priority Data
Dec. 1, 2023 (CN) 202311669152.6

(51) Int. Cl. H10K 59/122; H10K 59/12

(52) U.S. Cl. CPC H10K 59/122; H10K 59/1201

(57) ABSTRACT

A display panel, a display apparatus, and a method for manufacturing a display panel. The display panel includes: a base plate; a first electrode layer including a plurality of first electrodes; a light-transmitting electrically conductive layer including a light-transmitting electrically conductive portion; a pixel defining layer including a pixel defining portion and a first opening; and an isolation structure arranged at a side of the pixel defining layer away from the base plate, an isolation opening and a light-transmitting opening being surrounded by the isolation structure, an orthographic projection of the isolation opening on the base plate at least partially overlapping an orthographic projection of the first opening on the base plate, and an orthographic projection of the light-transmitting opening on the base plate at least partially overlapping an orthographic projection of the light-transmitting electrically conductive portion on the base plate.

### CROSS REFERENCE TO RELATED APPLICATION

The present application claims priority to Chinese Patent Application No. 202311669152.6 filed on Dec. 1, 2023, which is incorporated herein by reference in its entirety.

### TECHNICAL FIELD

The present application relates to the technical field of display device, and particularly to a display panel, a display apparatus, and a method for manufacturing a display panel.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the processing property of the current OLED display products needs to be improved.

### SUMMARY

Embodiments of the present application provide a display panel, a display apparatus, and a method for manufacturing a display panel, aiming to improve the processing property of the display panel.

Some embodiments of a first aspect of the present application provide a display panel, including: a base plate; a first electrode layer arranged at one side of the base plate and including a plurality of first electrodes distributed at intervals; a light-transmitting electrically conductive layer arranged at one side of the base plate and including a light-transmitting electrically conductive portion; a pixel defining layer arranged at a side of the first electrode layer away from the base plate and covering at least a portion of the light-transmitting electrically conductive portion, the pixel defining layer including a pixel defining portion and a first opening arranged in the pixel defining portion; a light-emitting layer including a light-emitting unit located within the first opening; and an isolation structure arranged at a side of the pixel defining layer away from the base plate, an isolation opening and a light-transmitting opening being surrounded by the isolation structure, an orthographic projection of the isolation opening on the base plate at least partially overlapping an orthographic projection of the first opening on the base plate, and an orthographic projection of the light-transmitting opening on the base plate at least partially overlapping an orthographic projection of the light-transmitting electrically conductive portion on the base plate.

Some embodiments of a second aspect of the present application further provide a display apparatus including the display panel according to any one of the above embodiments of the first aspect.

Some embodiments of a third aspect of the present application further provide a method for manufacturing a display panel, including: arranging a first electrode material layer on a base plate and patterning the first electrode material layer to form a first electrode layer including a plurality of first electrodes arranged at intervals; arranging an electrically conductive functional material layer on the base plate and patterning the electrically conductive functional material layer to obtain a light-transmitting electrically conductive layer including a light-transmitting electrically conductive portion; arranging a pixel defining material layer on the base plate; preparing an isolation structure at a side of the pixel defining material layer away from the base plate, an isolation opening and a light-transmitting opening being surrounded by the isolation structure, an orthographic projection of the light-transmitting opening on the base plate at least partially overlapping an orthographic projection of the light-transmitting electrically conductive portion on the base plate; and patterning the pixel defining material layer exposed by the isolation opening to obtain a first opening.

The display panel according to the embodiments of the present application includes the base plate, and the first electrode layer, the light-transmitting electrically conductive layer, the pixel defining layer, and the isolation structure arranged on the base plate. The pixel defining portion of the pixel defining layer includes the first openings for accommodating the light-emitting units. The orthographic projection of the first opening on the base plate at least partially overlaps the orthographic projection of the first electrode of the first electrode layer on the base plate, so that the first electrode can drive the light-emitting unit within the first opening to emit light. The light-transmitting openings and the isolation openings are surrounded by the isolation structure, the isolation openings and the first openings are arranged accordingly, and thus the light emitting of the light-emitting unit is not affected. The light-transmitting openings can increase the light transmittance of the display panel. The light-transmitting electrically conductive layer includes the light-transmitting electrically conductive portions corresponding to the light-transmitting openings, and when subsequently preparing a touch control electrode and other components, the parasitic capacitance between the touch control electrode and other components and the electrically conductive lines or circuits in the base plate can be reduced. Therefore, with the light-transmitting electrically conductive portion, the embodiments of the present application can reduce the parasitic capacitance, thereby effectively improving the processing property of the display panel.

### BRIEF DESCRIPTION OF THE DRAWINGS

Other features, objects, and advantages of the present application will be more apparent from reading the following detailed description of non-limiting embodiments with reference to the accompanying drawings, in which the same or similar reference numerals denote the same or similar features.

FIG. 1 shows a schematic structure diagram of a display panel according to an embodiment of the present application;

FIG. 2 shows a sectional view at A-A in FIG. 1 in an example;

FIG. 3 shows a sectional view at A-A in FIG. 1 in another example;

FIG. 4 shows a sectional view at A-A of FIG. 1 in yet another example;

FIG. 5 shows a sectional view at A-A in FIG. 1 in yet another example;

FIG. 6 shows a partially enlarged schematic structure diagram of a display panel according to an embodiment of the present application;

FIG. 7 shows a partially enlarged schematic structure diagram of a display panel according to another embodiment of the present application;

FIG. 8 shows a partially enlarged schematic structure diagram of a display panel according to yet another embodiment of the present application;

FIG. 9 shows a sectional view at B-B in FIG. 8 in an example;

FIG. 10 shows a schematic flow chart of a method for manufacturing a display panel according to an embodiment of the present application;

FIGS. 11 to 15 show schematic process diagrams of a method for manufacturing a display panel according to an embodiment of the present application.

### REFERENCE NUMERALS

10, display panel;
100, base plate; 110, first power supply signal line;
200, first electrode layer; 210, first electrode;
300, light-transmitting electrically conductive layer; 310, first protection portion; 320, light-transmitting electrically conductive portion;
400, pixel defining layer; 410, pixel defining portion; 420, first opening; 430, second opening; 440, second protection portion; 450, first connecting hole; 460, second connecting hole; 470, light-emitting unit;
500, isolation structure; 501, first sub-layer; 502, second sub-layer; 503, third sub-layer; 510, isolation opening; 520, light-transmitting opening;
600, second electrode layer; 610, second electrode;
700, dam;
800, touch control functional layer; 810, touch control electrode; 820, bridging portion;
900, encapsulation layer; 910, encapsulation portion; 920, second encapsulation layer; 930, third encapsulation layer;
AA, display area; NA, non-display area.

### DETAILED DESCRIPTION

Features and exemplary embodiments of various aspects of the present application will be described in detail below. In the following detailed description, a number of specific details are presented to provide a full understanding of the present application. However, it is apparent to those skilled in the art that the present application can be implemented without some of these specific details. The following description of embodiments is only for providing a better understanding of the present application by illustrating examples of the present application. In the accompanying drawings and the following description, at least some well-known structures and techniques are not illustrated to avoid unnecessarily obscuring the present application; and the dimensions of some structures may be exaggerated for clarity. Furthermore, the features, structures, or characteristics described below may be combined in one or more embodiments in any suitable manner.

In the description of the present application, it should be noted that, unless otherwise indicated, term “a plurality of” means two or more; the orientation or positional relationships indicated by terms “up”, “down”, “left”, “right”, “inside”, “outside”, and the like are only for facilitating the description of the present application and simplifying the description, but not for indicating or implying that the device or element referred to must have a particular orientation, be constructed and operated in a particular orientation, and therefore should not be construed as limiting the present application. Furthermore, terms “first”, “second”, and the like are used only for description, and should not to be construed as indicating or implying relative importance.

Orientation terms in the following description are orientations shown in the drawings and are not intended to limit the specific structure of the embodiments of the present application. In the description of the present application, it should be further noted that, unless otherwise expressly specified and defined, terms “mount” and “connect” should be understood in a broad sense, e.g., a fixed connection, a removable connection, or an integrated connection; a direct connection, or an indirect connection. Those of ordinary skill in the art may understand the specific meaning of the above terms in the present application according to the context.

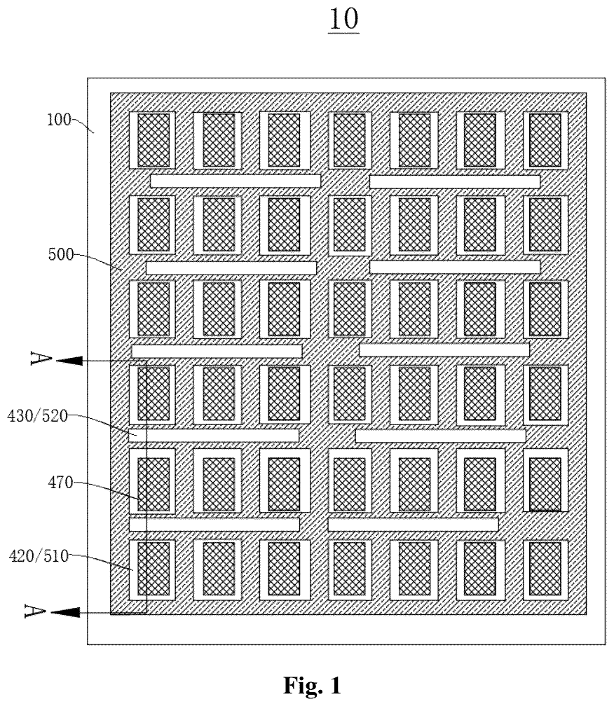

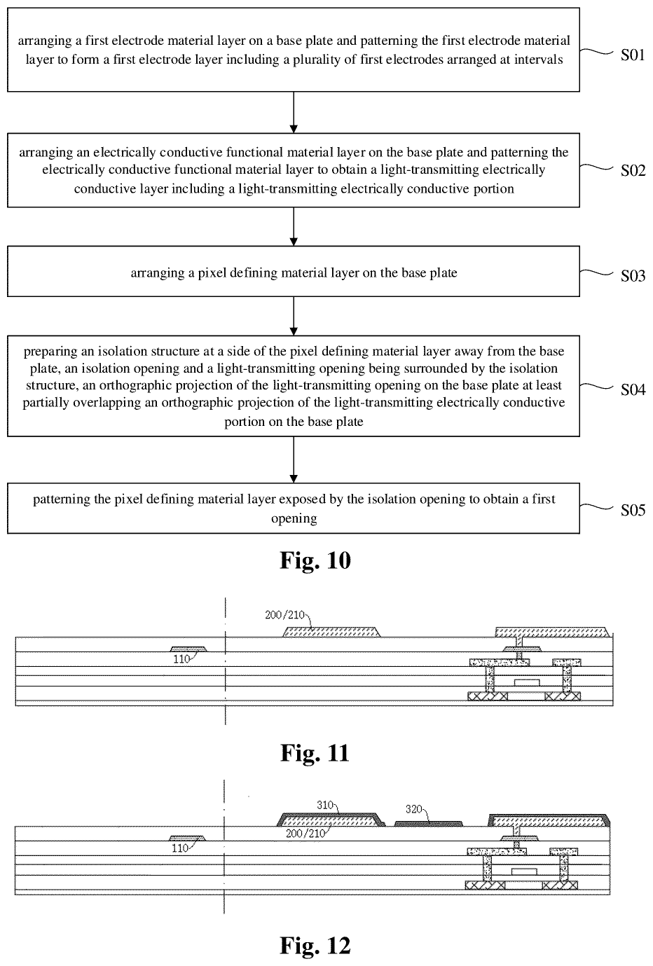

For a better understanding of the present application, the display panel, the display apparatus, and the method for manufacturing a display panel according to the embodiments of the present application are described in detail below in connection with FIGS. 1 to 15.

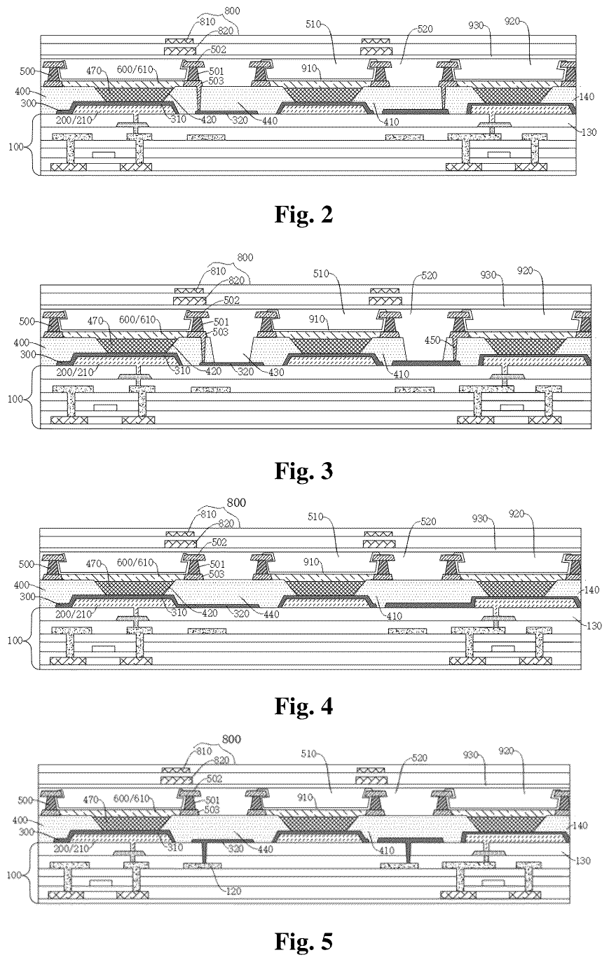

FIG. 1 shows a schematic structure diagram of a display panel 10 according to an embodiment of the present application, and FIG. 2 shows a sectional view at A-A in FIG. 1 in an example.

As shown in FIGS. 1 and 2, the embodiments of the first aspect of the present application provide a display panel 10 including a base plate 100, and a first electrode layer 200, a light-transmitting electrically conductive layer 300, a pixel defining layer 400, and an isolation structure 500 arranged on the base plate 100. The first electrode layer 200 is arranged on the base plate 100 and including a plurality of first electrodes 210 distributed at intervals; the light-transmitting electrically conductive layer 300 is arranged at one side of the base plate 100 and including a light-transmitting electrically conductive portion 320; the pixel defining layer 400 is arranged at a side of the first electrode layer 200 away from the base plate 100 and covering at least a portion of the light-transmitting electrically conductive portion 320, the pixel defining layer 400 includes a pixel defining portion 410 and a first opening 420 arranged in the pixel defining portion 410; a light-emitting layer includes a light-emitting unit 470 located within the first opening 420; and the isolation structure 500 is arranged at a side of the pixel defining layer 400 away from the base plate 100, an isolation opening 510 and a light-transmitting opening 520 are surrounded by the isolation structure 500, an orthographic projection of the isolation opening 510 on the base plate 100 at least partially overlaps an orthographic projection of the first opening 420 on the base plate 100, and an orthographic projection of the light-transmitting opening 520 on the base plate 100 at least partially overlaps an orthographic projection of the light-transmitting electrically conductive portion 320 on the base plate 100.

The display panel 10 according to the embodiments of the present application includes the base plate 100, and the first electrode layer 200, the light-transmitting electrically conductive layer 300, the pixel defining layer 400, and the isolation structure 500 arranged on the base plate 100. The pixel defining portion 410 of the pixel defining layer 400 includes the first openings 420 for accommodating the light-emitting units 470. The orthographic projection of the first opening 420 on the base plate 100 at least partially overlaps the orthographic projection of the first electrode 210 of the first electrode layer 200 on the base plate 100, so that the first electrode 210 can drive the light-emitting unit 470 within the first opening 420 to emit light. The light-transmitting openings 520 and the isolation openings 510 are surrounded by the isolation structure 500, the isolation openings 510 and the first openings 420 are arranged accordingly, and thus the light emitting of the light-emitting unit 470 is not affected. The light-transmitting openings 520 can increase the light transmittance of the display panel 10. The light-transmitting electrically conductive layer 300 includes the light-transmitting electrically conductive portions 320 corresponding to the light-transmitting openings 520, and when subsequently preparing a touch control electrode 810 and other components, the parasitic capacitance between the touch control electrode 810 and other components and the electrically conductive lines or circuits in the base plate 100 can be reduced. Therefore, with the light-transmitting electrically conductive portion 320, the embodiments of the present application can reduce the parasitic capacitance, thereby effectively improving the processing property of the display panel 10.

The base plate 100 may be arranged in various ways. For example, the base plate 100 may include a substrate, and a first electrically conductive layer, a second electrically conductive layer, and a third electrically conductive layer arranged at one side of the substrate and being stacked. An electrically insulating layer is arranged between any adjacent electrically conductive layers. Exemplarily, a pixel drive circuit arranged on the base plate 100 includes a transistor and a storage capacitor. The transistor includes a semiconductor, a gate, a source, and a drain. The storage capacitor includes a first electrode plate and a second electrode plate. As an example, the gate and the first electrode plate may be located in the first electrically conductive layer, the second electrode plate may be located in the second electrically conductive layer, and the source and the drain may be located in the third electrically conductive layer. Optionally, the base plate 100 may further include a fourth electrically conductive layer located at a side of the third electrically conductive layer away from the base plate, and the fourth electrically conductive layer may include a connecting signal line, so that the first electrode 210 is connected with the drive circuit through the connecting signal line, and for example, the first electrode 210 is connected with the source or the drain of the drive transistor through the connecting signal line.

The first electrode 210 is, for example, an anode, and the material of the first electrode 210 may include at least one of indium tin oxide or indium zinc oxide. For example, the material of the first electrode 210 includes indium tin oxide to further increase the light transmittance of the display panel 10. Optionally, the material of the first electrode 210 may further include silver, and the first electrode 210 includes, for example, a silver metal layer, an indium tin oxide layer, and a silver metal layer that are stacked, thereby protecting the silver metal layer through the indium tin oxide layer.

The material of the light-transmitting electrically conductive layer 300 may be set in various ways, and for example, the material of the light-transmitting electrically conductive layer 300 includes at least one of indium tin oxide or indium zinc oxide, so as to further increase the light transmittance of the display panel 10.

In some optional embodiments, the light-transmitting electrically conductive layer 300 is arranged at a side of the first electrode 210 away from the base plate 100, which can reduce effect of the preparation of the light-transmitting electrically conductive layer 300 on the first electrode 210.

Optionally, the light-transmitting electrically conductive layer 300 further includes a first protection portion 310 covering at least a portion of the first electrode 210. When a light-transmitting electrically conductive material is patterned to form the first protection portion 310 and the light-transmitting electrically conductive portion 320 of the light-transmitting electrically conductive layer 300, the material on the first electrode 210 may be retained to form the first protection portion 310, which can prevent the process for patterning the light-transmitting electrically conductive material from damaging the first electrode 210.

Optionally, the orthographic projection of the first opening 420 on the base plate 100 at least partially overlaps an orthographic projection of the first protection portion 310 on the base plate 100. For example, the orthographic projection of the first opening 420 on the base plate 100 is located within the orthographic projection of the first protection portion 310 on the base plate 100, so that the first electrode 210 can drive the light-emitting unit 470 to emit light through the first protection portion 310 and the first opening 420.

Optionally, the first electrode 210 includes a first sub-layer, a second sub-layer, and a third sub-layer stacked in a direction away from the base plate 100, the first protection portion 310 is located at a side of the third sub-layer away from the second sub-layer. That is, the first protection portion 310 is a layer structure arranged covering the first electrode 210, rather than a layer structure within the first electrode 210. The first sub-layer and the third sub-layer may each be the silver metal layer as described above, and the second sub-layer may be the indium tin oxide layer as described above.

The relative positional relationship between the first protection portion 310 and the light-transmitting electrically conductive portion 320 may be set in various ways. For example, as shown in FIG. 4, one first protection portion 310 and at least one light-transmitting electrically conductive portion 320 are interconnected to form the light-transmitting electrically conductive portion, the light-transmitting electrically conductive layer 300 may include a plurality of light-transmitting electrically conductive portions, and the light-transmitting electrically conductive portions are spaced apart and electrically insulated from each other. In this way, the light-transmitting electrically conductive portion 320 may have the same potential as the first protection portion 310, and thus has the same potential as the first electrode 210. The plurality of light-transmitting electrically conductive portions are spaced apart and electrically insulated from each other, which can avoid short circuit of different first electrodes 210 through the light-transmitting electrically conductive portions.

In some other optional embodiments, as shown in FIG. 5, the light-transmitting electrically conductive layer 300 may include a plurality of first protection portions 310, the first protection portions 310 and the light-transmitting electrically conductive portions 320 are arranged at intervals and electrically insulated from each other, the base plate 100 further includes a second power supply signal line 120, and the light-transmitting electrically conductive portion 320 and the second power supply signal line 120 are interconnected. For example, a layer structure between the second power supply signal line 120 and the light-transmitting electrically conductive portion 320 includes a via, and the light-transmitting electrically conductive portion 320 and the second power supply signal line 120 are connected through the via, so that the light-transmitting electrically conductive portion 320 can have a fixed potential, which can further reduce the parasitic capacitance. For example, the second power supply signal line 120 may be a drive power supply voltage signal line.

In some other embodiments, the first protection portion 310 and the light-transmitting electrically conductive portion 320 in the light-transmitting electrically conductive layer 300 are spaced apart to avoid short circuit between the first protection portion 310 and the light-transmitting electrically conductive portion 320. The first protection portion 310 is located at a side of the first electrode layer 200 away from the base plate 100, the orthographic projection of the first protection portion 310 on the base plate 100 at least partially overlaps the orthographic projection of the first electrode 210 on the base plate 100, and the first protection portion 310 covers at least a portion of the surface of the first electrode 210 away from the base plate 100, so that the first protection portion 310 can protect the first electrode 210. If the material of the light-transmitting electrically conductive layer 300 is the same as the material of the first electrode layer 200, during the preparation process of the display panel 10, the first protection portion 310 on the first electrode 210 may be retained, so as to reduce damage to the first electrode 210 due to the removing of the first protection portion 310, improve the service life of the first electrode 210, and increase the yield of the display panel 10.

Optionally, the material of the pixel defining layer 400 may be an inorganic material or an organic material. Herein, the material of the pixel defining layer 400 is an inorganic material, on the one hand, the thickness of the pixel defining layer 400 can be appropriately reduced to reduce the overall thickness of the display panel 10, and on the other hand, it is easier to control the shape of the second opening 430 and control the angle of inclination of the wall of the pixel defining portion 410 towards the second opening 430.

In some optional embodiments, as shown in FIG. 3, the pixel defining portion 410 further includes a second opening 430, an orthographic projection of the second opening 430 on the base plate 100 is located within the orthographic projection of the light-transmitting opening 520 on the base plate 100. In these embodiments, at least a portion of the pixel defining layer 400 on the light-transmitting electrically conductive portion 320 may be removed to further increase the light transmittance of the display panel 10.

In some other optional embodiments, as shown in FIG. 2, the pixel defining layer 400 further includes a second protection portion 440 located at a side of the light-transmitting electrically conductive portion 320 away from the base plate 100.

In these optional embodiments, the second protection portion 440 is arranged on the light-transmitting electrically conductive portion 320, so that during the etching process for preparing the isolation structure 500, damage to the light-transmitting electrically conductive portion 320 in this process can be reduced, which can increase the yield of the light-transmitting electrically conductive portion 320 and increase the process yield of the display panel 10.

Optionally, the second protection portion 440 may be located in the pixel defining layer 400, i.e., the second protection portion 440 and the pixel defining portion 410 may be arranged in a same layer. When preparing the pixel defining layer 400, the material on the light-transmitting electrically conductive portion 320 may be retained to form the second protection portion 440, which can simplify the preparation process of the display panel 10 and improve the preparation efficiency of the display panel 10.

Optionally, the orthographic projection of the light-transmitting electrically conductive portion 320 on the base plate 100 is located within an orthographic projection of the second protection portion 440 on the base plate 100, so that the second protection portion 440 can more comprehensively protect the light-transmitting electrically conductive portion 320.

Optionally, the orthographic projection of the light-transmitting opening 520 on the base plate 100 is located within the orthographic projection of the second protection portion 440 on the base plate 100, so as to further reduce the effect of preparing the light-transmitting opening 520 in the isolation structure 500 on the light-transmitting electrically conductive portion 320.

In some optional embodiments, the isolation structure 500 and the light-transmitting electrically conductive portion 320 may be interconnected, so that the light-transmitting electrically conductive portion 320 has a fixed potential, which better reduces the parasitic capacitance.

Optionally, if the light-transmitting electrically conductive layer 300 includes the first protection portion 310, and the isolation structure 500 and the light-transmitting electrically conductive portion 320 are interconnected, then the first protection portion 310 and the light-transmitting electrically conductive portion 320 are spaced apart and electrically insulated from each other, thereby avoiding short circuit between the isolation structure 500 and the first electrode 210.

Optionally, as shown in FIG. 3, the pixel defining layer 400 includes a first connecting hole 450, the isolation structure 500 and the light-transmitting electrically conductive portion 320 are interconnected through the first connecting hole 450.

In these optional embodiments, with the first connecting hole 450 in the second protection portion 440, the isolation structure 500 and the light-transmitting electrically conductive portion 320 can be interconnected through the first connecting hole 450, and the light-transmitting electrically conductive portion 320 can have a fixed potential, which better reduces the parasitic capacitance.

Optionally, at least one first connecting hole 450 is arranged corresponding to each light-transmitting electrically conductive portion 320, i.e., each light-transmitting electrically conductive portion 320 and the isolation structure 500 are interconnected through at least one first connecting hole 450, so that each light-transmitting electrically conductive portion 320 can have a fixed potential.

Optionally, an orthographic projection of the first connecting hole 450 on the base plate 100 is located within an orthographic projection of the isolation structure 500 on the base plate 100, i.e., the first connecting hole 450 is located at a side of the isolation structure 500 towards the base plate 100, covered by the isolation structure 500, and spaced apart from the light-transmitting opening 520 and the isolation opening 510, which can reduce the effect of preparing the light-transmitting opening 520 and the isolation opening 510 on the light-transmitting electrically conductive portion 320 through first connecting hole 450.

The shape of the first connecting hole 450 may be set in various ways, as shown in FIG. 6, the first connecting hole 450 may be in the shape of a ring around the light-transmitting opening 520, so that the isolation structure 500 located at the periphery of the light-transmitting opening 520 can all be connected with the light-transmitting electrically conductive portion 320 through the first connecting hole 450, which can increase the contact area between the isolation structure 500 and the light-transmitting electrically conductive portion 320 and increase the connection yield between the isolation structure 500 and the light-transmitting electrically conductive portion 320.

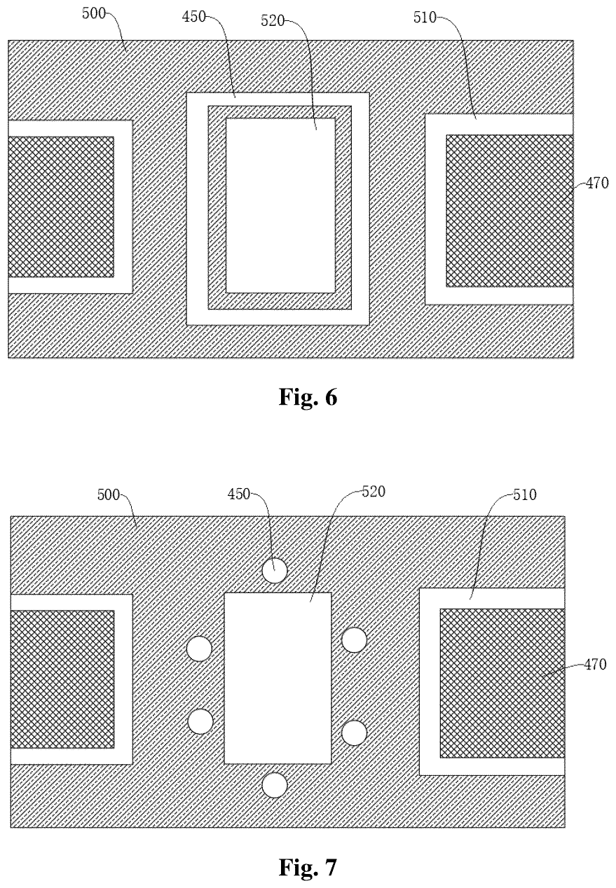

In some other optional embodiments, as shown in FIG. 7, at least one first connecting hole 450 is arranged at at least one side of the light-transmitting opening 520. For example, a plurality of first connecting holes 450 are arranged at intervals around the light-transmitting opening 520, so that isolation structures 500 located at different positions around the light-transmitting opening 520 can be connected with the light-transmitting electrically conductive portion 320 through different first connecting holes 450.

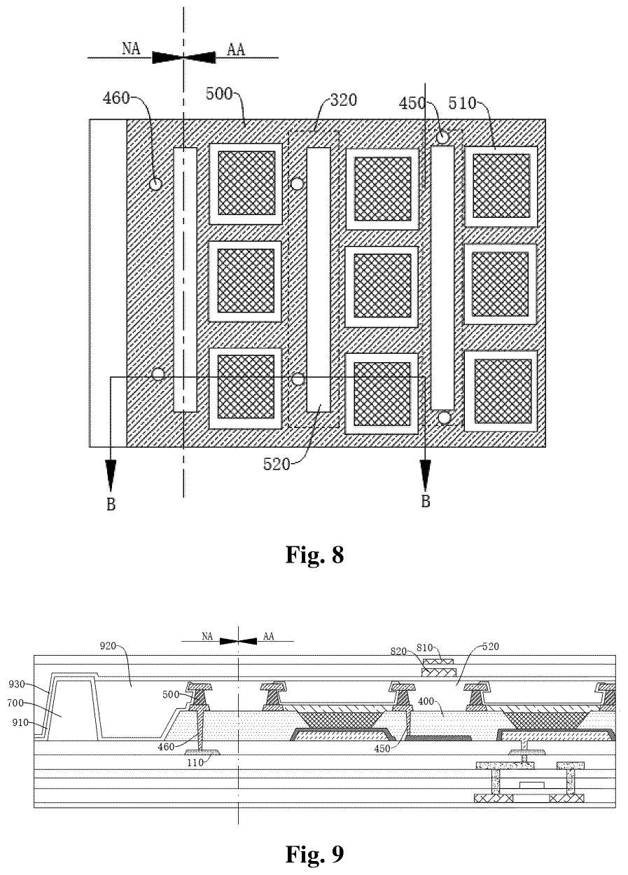

Optionally, as shown in FIGS. 8 and 9, the display panel 10 includes a display area AA, both the first opening 420 and the isolation opening 510 may be located in the display area AA, and the light-emitting unit 470 emits light for display in the display area AA. The first connecting hole 450 may be located in the display area AA and connect the isolation structure 500 and the light-transmitting electrically conductive portion 320 in the display area AA.

Optionally, the display panel 10 further includes a light-transmitting area, in which the sensors are correspondingly arranged, for example, an ambient light sensor, a fingerprint sensor, a camera, and the like are arranged under the light-transmitting area. The light-transmitting opening 520 may be located only in the light-transmitting area, or the light-transmitting opening 520 may be located in the light-transmitting area as well as in the display area AA other than the light-transmitting area. The light-transmitting area may be a portion of the display area AA, in which case the isolation structure 500 in the light-transmitting area is provided with the isolation opening 510 and the light-transmitting opening 520, and the light-emitting unit is arranged within the isolation opening 510, so that the light-transmitting area has display function and light-transmitting function.

The isolation structure 500 may be arranged in various ways. For example, the isolation structure 500 includes a first sub-layer 501 and a second sub-layer 502 located at a side of the first sub-layer 501 away from the base plate 100, an orthographic projection of the first sub-layer 501 on the base plate 100 is located within an orthographic projection of the second sub-layer 502 on the base plate 100. Therefore, the area of the orthographic projection of the second sub-layer 502 is greater than the area of the orthographic projection of the first sub-layer 501, and a recess may be formed under the second sub-layer 502. In subsequently preparing the light-emitting unit 470, the light-emitting material may be disconnected at the edge of the second sub-layer 502, so that a precision mask plate process can be omitted, and the preparation process of the display panel 10 can be simplified.

Optionally, as described above, if the isolation structure 500 includes the first sub-layer 501 and the second sub-layer 502, the first sub-layer 501 and the light-transmitting electrically conductive portion 320 are interconnected through the first connecting hole 450. The first sub-layer 501 is closer to the light-transmitting electrically conductive portion 320 than the second sub-layer 502, and the first sub-layer 501 is more easily interconnected with the light-transmitting electrically conductive portion 320 through the first connecting hole 450.

The first sub-layer 501 and the light-transmitting electrically conductive portion 320 may be interconnected directly. Alternatively, in some other embodiments, the isolation structure 500 further includes a third sub-layer 503 located at a side of the first sub-layer 501 towards the base plate 100, the orthographic projection of the first sub-layer 501 on the base plate 100 is located within an orthographic projection of the third sub-layer 503 on the base plate 100, the third sub-layer 503 and the light-transmitting electrically conductive portion 320 are interconnected through the first connecting hole 450 to connect the first sub-layer 501 to the light-transmitting electrically conductive portion 320 through the third sub-layer 503.

In addition, by arranging the third sub-layer 503, when the first sub-layer 501 is laterally etched such that the orthographic projection of the first sub-layer 501 on the base plate 100 is located within the orthographic projection of the second sub-layer 502 on the base plate 100, the material under the third sub-layer 503 can be protected to avoid damage to the layer structure under the third sub-layer 503.

In some embodiments, the display panel 10 further includes a second electrode layer 600 including a second electrode 610 located at a side of the light-emitting unit 470 away from the base plate 100, the second electrode 610 is connected with the isolation structure 500. Therefore, a plurality of second electrodes 610 may be interconnected through the isolation structure 500 as a planar electrode.

The second electrode 610 and the first sub-layer 501 of the isolation structure 500 may be interconnected. Optionally, if the isolation structure 500 includes the third sub-layer 503, the second electrode 610 may be further connected with the third sub-layer 503 of the isolation structure 500, or the second electrode 610 may be connected with the first sub-layer 501 and the third sub-layer 503 of the isolation structure 500.

Optionally, the first sub-layer 501 includes an electrically conductive material, and the second electrode 610 and the first sub-layer 501 are electrically connected with each other. Optionally, the second sub-layer 502 may also include an electrically conductive material, so as to increase the distribution area of the electrically conductive portion in the isolation structure 500 and reduce the overall resistance of the second electrode 610. Optionally, the third sub-layer 503 includes an electrically conductive material, so as to further increase the distribution area of the electrically conductive portion in the isolation structure 500 and reduce the overall resistance of the second electrode 610.

In some optional embodiments, as shown in FIG. 9, the display panel 10 further includes a first power supply signal line 110 located within the base plate 100 or at one side of the base plate 100, the pixel defining portion 410 includes a second connecting hole 460, the isolation structure 500 is connected with the first power supply signal line 110 through the second connecting hole 460.

In these optional embodiments, the pixel defining portion 410 further includes the second connecting hole 460, so that the isolation structure 500 can be connected with the first power supply signal line 110 within the base plate 100 through the second connecting hole 460 to achieve the mutual transmission of the signal lines.

Optionally, the first power supply signal line 110 may be located in the fourth electrically conductive layer to reduce the distance between the first power supply signal line 110 and the isolation structure 500, which facilitates the electrical connection between the first power supply signal line 110 and the isolation structure 500.

Optionally, both the pixel defining portion 410 and the second protection portion 440 are portions of the pixel defining layer 400, the pixel defining portion 410 and the second protection portion 440 are components in different areas on the pixel defining layer 400, and there may be no distinct boundary between the pixel defining portion 410 and the second protection portion 440. The second connecting hole 460 and the first connecting hole 450 may be prepared in a same process, so as to further simplify the preparation process of the display panel 10.

Optionally, the display panel 10 further includes a non-display area NA arranged around at least a portion of the display area AA. The second connecting hole 460 may be located in the non-display area NA, so that the isolation structure 500 is electrically connected with the first power supply signal line 110 in the non-display area NA, which reduces the effect of the second connecting hole 460 on the structures within the display area AA.

Optionally, a dam structure 700 is further arranged on the base plate 100 of the display panel 10, the dam structure 700 is arranged around the display area AA, and the second connecting hole 460 may be arranged at a side of the dam structure 700 towards the display area AA, so that the isolation structure 500 can be entirely located at the side of the dam structure 700 towards the display area AA, which can simplify the structure of the isolation structure 500.

Optionally, the display panel 10 further includes an encapsulation layer 900 which may include a first encapsulation layer, the first encapsulation layer includes an encapsulation portion 910 located at a side of the second electrode 610 away from the base plate 100, and the encapsulation portion 910 may provide seal protection to the light-emitting unit 470. The first encapsulation layer may include an inorganic material.

Optionally, the encapsulation layer 900 further includes a second encapsulation layer 920 located at a side of the first encapsulation layer away from the base plate 100, the second encapsulation layer 920 is located at a side of the dam structure 700 towards the display area AA, and the dam structure 700 may reduce the spillage of the material of the second encapsulation layer 920 to a side of the dam structure 700 away from the display area AA. The second encapsulation layer 920 may include an organic material.

Optionally, the second encapsulation layer 920 and at least a portion of the second protection portion 440 are connected in contact, for example, the first encapsulation layer 900 does not encapsulate the light-transmitting opening 520, while the first encapsulation layer 900 only encapsulated the area where the isolation opening 510 is located, so that the second encapsulation layer 920 can be connected in direct contact with the second protection portion 440 within the light-transmitting opening 520.

Optionally, the encapsulation layer 900 further includes a third encapsulation layer 920 located at a side of the second encapsulation layer 920 away from the base plate 100, and the material of the third encapsulation layer 920 may be the same as the material of the first encapsulation layer, for example, the material of the third encapsulation layer 920 is an inorganic material.

Optionally, the display panel 10 further includes a touch control functional layer 800 located at a side of the encapsulation layer 900 away from the base plate 100. The touch control functional layer 800 may include a first touch control layer and a second touch control layer, and an electrically insulating layer is arranged between the first touch control layer and the second touch control layer. A touch control electrode 810 is arranged within one of the first touch control layer and the second touch control layer, a bridging portion 820 is arranged within the other one of the first touch control layer and the second touch control layer, and the bridging portion 820 is used to connect the adjacent touch control electrodes 810.

Optionally, the orthographic projection of at least a portion of the touch control electrodes 810 on the base plate 100 at least partially overlaps the orthographic projection of the light-transmitting opening 520 on the base plate 100. During the arrangement of the touch control electrodes 810, a portion of the touch control electrodes 810 will be located above the light-transmitting opening 520, i.e., the orthographic projection of a portion of the touch control electrodes 810 on the base plate 100 at least partially overlaps the orthographic projection of the light-transmitting opening 520 on the base plate 100, and in such cases, since the light-transmitting electrically conductive portion 320 is arranged corresponding to the light-transmitting opening 520, the light-transmitting electrically conductive portion 320 provides shielding function, which can reduce parasitic capacitance generated between the touch control electrodes 810 and other signal lines within the base plate 100, thereby improving the stability of the touch control signal transmission.

In some optional embodiments, the orthographic projection of the first electrode 210 on the base plate 100 is located within the orthographic projection of the first protection portion 310 on the base plate 100. Therefore, the size of the first protection portion 310 is greater than the size of the first electrode 210, and the first protection portion 310 can more comprehensively protect the first electrode 210.

Optionally, the first electrode 210 includes a top surface away from the base plate 100 and a side surface connected with the periphery of the top surface and extending towards the base plate 100, and the first protection portion 310 can cover the top surface and the side surface, so as to avoid damage to the first electrode 210 through the top surface or the side surface when the light-transmitting electrically conductive layer 300 is patterned.

Optionally, the first protection portion 310 includes a center area located at a side of the first protection portion 310 away from the base plate 100 and an edge area connected to the periphery of the center area and connected in contact with the base plate 100. The first protection portion 310 is larger than the first electrode 210 and protrudes from the first electrode 210 to form the edge area in contact with the base plate 100, so that the first protection portion 310 can more comprehensively protect the first electrode 210.

The embodiments of the second aspect of the present application further provide a display apparatus including the display panel 10 of any of the above embodiments of the first aspect. Since the display apparatus according to the embodiments of the second aspect of the present application includes the display panel 10 of any of the above embodiments of the first aspect, the display apparatus according to the embodiments of the second aspect of the present application has the same beneficial effects as those of the display panel 10 of any of the above embodiments of the first aspect, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line telephone, a console, and other apparatus with display function.

The embodiments of the third aspect of the present application further provide a method for manufacturing a display panel 10, which may be the display panel 10 according to any of the above embodiments of the first aspect. As shown in FIGS. 1 to 10, the method for manufacturing the display panel 10 may include:

step S01: as shown in FIG. 11, arranging a first electrode 210 material layer on a base plate 100 and patterning the first electrode 210 material layer to form a first electrode layer 200 including a plurality of first electrodes 210 arranged at intervals;

step S02: as shown in FIG. 12, arranging an electrically conductive functional material layer on the base plate 100 and patterning the electrically conductive functional material layer to obtain a light-transmitting electrically conductive layer 300 including a light-transmitting electrically conductive portion 320;

Optionally, as shown in FIG. 12, in step S02, the light-transmitting electrically conductive layer 300 further includes a first protection portion 310 covering at least a portion of the first electrode 210, so that the first protection portion 310 can protect the first electrode 210.

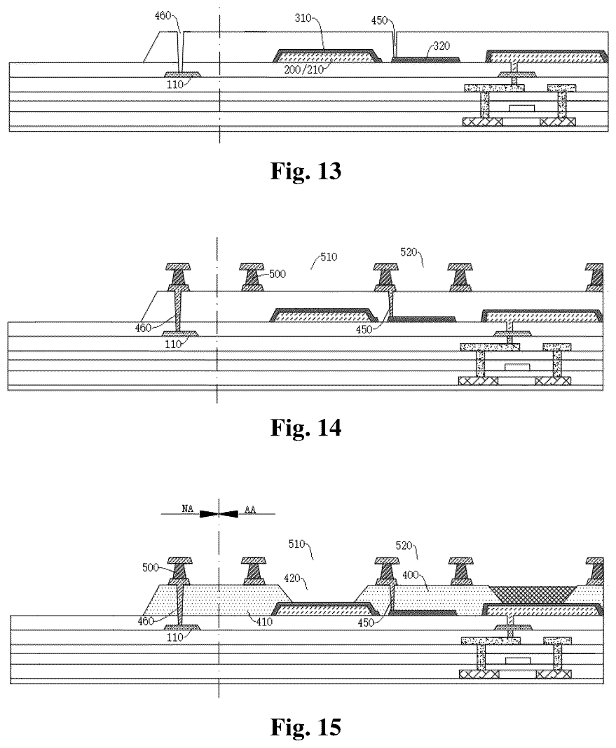

step S03: as shown in FIG. 13, arranging a pixel defining material layer on the base plate 100;

step S04: as shown in FIG. 14, preparing an isolation structure 500 at a side of the pixel defining material layer away from the base plate 100, an isolation opening 510 and a light-transmitting opening 520 being surrounded by the isolation structure 500, an orthographic projection of the light-transmitting opening 520 on the base plate 100 at least partially overlapping an orthographic projection of the light-transmitting electrically conductive portion 320 on the base plate 100;

step S05: as shown in FIG. 15, patterning the pixel defining material layer exposed by the isolation opening 510 to obtain a first opening 420.

Optionally, if the light-transmitting electrically conductive layer 300 includes the first protection portion 310, at least a portion of the first protection portion 310 is exposed by the first opening 420, which facilitate subsequent connection of the light-emitting unit 470 with the first electrode 210 through the first protection portion 310.

In the method for manufacturing the display panel 10 according to the embodiments of the present application, after preparing the first electrode layer 200, the light-transmitting electrically conductive layer 300 is then prepared, and when the electrically conductive functional material layer is patterned, the first protection portion 310 located on the first electrode 210 is retained, so as to alleviate the problem that the first electrode 210 is likely to be damaged in this process. In addition, only after the isolation structure 500 is prepared, the pixel defining material layer is patterned to obtain the first opening 420 in step S05, so that the pixel defining material layer can better protect the light-transmitting electrically conductive layer 300 in step S04, which reduces the effect on the light-transmitting electrically conductive layer 300 when obtaining the isolation structure 500 by patterning, and the processing property of the display panel 10 can be improved.

In addition, the first opening 420 is configured to accommodate the light-emitting unit 470, and the orthographic projection of the first opening 420 on the base plate 100 at least partially overlaps the orthographic projection of the first electrode 210 of the first electrode layer 200 on the base plate 100, so that the first electrode 210 can drive the light-emitting unit 470 within the first opening 420 to emit light. The light-transmitting openings 520 and the isolation openings 510 are surrounded by the isolation structure 500, the isolation openings 510 and the first openings 420 are arranged accordingly, and thus the light emitting of the light-emitting unit 470 is not affected. The light-transmitting openings 520 can increase the light transmittance of the display panel 10, the light-transmitting electrically conductive portions 320 are corresponding to the light-transmitting openings 520, and when subsequently preparing a touch control electrode 810 and other components, the parasitic capacitance between the touch control electrode 810 and other components and the electrically conductive lines or circuits in the base plate 100 can be reduced. Therefore, with the first protection portion 310 and the light-transmitting electrically conductive portion 320, the embodiments of the present application can not only alleviate the problem that the first electrode 210 is likely to be damaged during the preparation process, but also reduce the parasitic capacitance, thereby effectively improving the processing property of the display panel 10.

In some optional embodiments, when patterning the pixel defining material in step S05, a portion of the pixel defining material layer located at a side of the light-transmitting electrically conductive portion 320 away from the base plate 100 may be retained to form a second protection portion 440, which can protect the light-transmitting electrically conductive portion 320. Alternatively, in step S05, a portion of the pixel defining material layer located on the light-transmitting electrically conductive portion 320 may be removed to form a second opening 430, so as to further increase the light transmittance of the display panel 10.

In some optional embodiments, as shown in FIG. 13, in step S03, the pixel defining material layer may be patterned to obtain a first connecting hole 450, a portion of the light-transmitting electrically conductive portion 320 is exposed by the first connecting hole 450. When preparing the isolation structure 500 in subsequent step S04, the isolation structure 500 can be connected with the light-transmitting electrically conductive portion 320 through the first connecting hole 450, so that the light-transmitting electrically conductive portion 320 can have a fixed potential, which can further reduce the parasitic capacitance.

Optionally, the display panel 10 further includes a first power supply signal line 110 located within the base plate 100 or at one side of the base plate 100, and in step S03, the pixel defining material layer may be patterned to further obtain a second first connecting hole 460, a portion of the first power supply signal line 110 is exposed by the second connecting hole 460. When preparing the isolation structure 500 in subsequent step S04, the isolation structure 500 can be connected with the first power supply signal line 110 through the second first connecting hole 460.

Although the present application has been described with reference to the preferred embodiments, various improvements can be made and parts thereof can be replaced with equivalents without departing from the scope of the present application. In particular, as long as there is no structural conflict, the technical features described in the various embodiments can be combined in any manner. The present application is not limited to the particular embodiments disclosed herein, but includes all technical solutions falling within the scope of the claims.

What is claimed is:

1. A display panel, comprising:
a base plate;
a first electrode layer arranged at one side of the base plate and comprising a plurality of first electrodes distributed at intervals;
a light-transmitting electrically conductive layer arranged at one side of the base plate and comprising a light-transmitting electrically conductive portion;
a pixel defining layer arranged at a side of the first electrode layer away from the base plate and covering at least a portion of the light-transmitting electrically conductive portion, the pixel defining layer comprising a pixel defining portion and a first opening arranged in the pixel defining portion;
a light-emitting layer comprising a light-emitting unit located within the first opening; and
an isolation structure arranged at a side of the pixel defining layer away from the base plate, an isolation opening and a light-transmitting opening being surrounded by the isolation structure, an orthographic projection of the isolation opening on the base plate at least partially overlapping an orthographic projection of the first opening on the base plate, and an orthographic projection of the light-transmitting opening on the base plate at least partially overlapping an orthographic projection of the light-transmitting electrically conductive portion on the base plate.

2. The display panel according to claim 1, wherein
the light-transmitting electrically conductive layer is arranged at a side of the first electrode layer away from the base plate.

3. The display panel according to claim 1, wherein the light-transmitting electrically conductive layer further comprises a first protection portion covering at least a portion of the first electrode;
the orthographic projection of the first opening on the base plate at least partially overlaps an orthographic projection of the first protection portion on the base plate;
the first electrode comprises a first sub-layer, a second sub-layer, and a third sub-layer stacked in a direction away from the base plate, the first protection portion is located at a side of the third sub-layer away from the second sub-layer;
an orthographic projection of the first electrode on the base plate is located within the orthographic projection of the first protection portion on the base plate.

4. The display panel according to claim 3, wherein, one first protection portion and at least one light-transmitting electrically conductive portion are interconnected to form the light-transmitting electrically conductive portion, the light-transmitting electrically conductive layer comprises a plurality of light-transmitting electrically conductive portions, and the light-transmitting electrically conductive portions are spaced apart and electrically insulated from each other; or the light-transmitting electrically conductive layer comprises a plurality of first protection portions, the first protection portions and the light-transmitting electrically conductive portions are arranged at intervals, the base plate comprises a second power supply signal line, and the light-transmitting electrically conductive portion and the second power supply signal line are interconnected.

5. The display panel according to claim 1, wherein
the pixel defining portion comprises a second opening, an orthographic projection of the second opening on the base plate at least partially overlaps the orthographic projection of the light-transmitting opening on the base plate.

6. The display panel according to claim 1, wherein the display panel further comprises a second protection portion located at a side of the light-transmitting electrically conductive portion away from the base plate.

7. The display panel according to claim 6, wherein the orthographic projection of the light-transmitting electrically conductive portion on the base plate is located within an orthographic projection of the second protection portion on the base plate;
the orthographic projection of the light-transmitting opening on the base plate is located within the orthographic projection of the second protection portion on the base plate;
the second protection portion and the pixel defining portion are arranged in a same layer.

8. The display panel according to claim 1, wherein
the isolation structure and the light-transmitting electrically conductive portion are electrically connected with each other.

9. The display panel according to claim 1, wherein the pixel defining layer comprises a first connecting hole, the isolation structure and the light-transmitting electrically conductive portion are interconnected through the first connecting hole;
at least one first connecting hole is arranged corresponding to each light-transmitting electrically conductive portion;
the first connecting hole is in the shape of a ring around the light-transmitting opening; or at least one first connecting hole is arranged at at least one side of the light-transmitting opening;
the first connecting hole is located in a display area of the display panel.

10. The display panel according to claim 9, wherein the isolation structure comprises a first sub-layer and a second sub-layer located at a side of the first sub-layer away from the base plate, an orthographic projection of the first sub-layer on the base plate is located within an orthographic projection of the second sub-layer on the base plate, the first sub-layer and the light-transmitting electrically conductive portion are interconnected through the first connecting hole.

11. The display panel according to claim 10, wherein the isolation structure further comprises a third sub-layer located at a side of the first sub-layer towards the base plate, the orthographic projection of the first sub-layer on the base plate is located within an orthographic projection of the third sub-layer on the base plate, the third sub-layer and the light-transmitting electrically conductive portion are interconnected through the first connecting hole to connect the first sub-layer to the light-transmitting electrically conductive portion through the third sub-layer.

12. The display panel according to claim 11, wherein the display panel further comprises a second electrode layer comprising a second electrode located at a side of the light-emitting unit away from the base plate, the second electrode is connected with the isolation structure;
the second electrode and the first sub-layer are interconnected;
the second electrode and the third sub-layer are interconnected.

13. The display panel according to claim 1, wherein the display panel further comprises a first power supply signal line located within the base plate or at one side of the base plate, the pixel defining portion comprises a second connecting hole, the isolation structure is connected with the first power supply signal line through the second connecting hole;
the second connecting hole is located in a non-display area of the display panel;
at least a portion of the first power supply signal line is located in the non-display area of the display panel.

14. The display panel according to claim 13, wherein the base plate further comprises a dam structure located in the non-display area of the display panel, the dam structure is arranged around a display area of the display panel, the second connecting hole is located at a side of the dam structure towards the display area.

15. A display apparatus comprising the display panel according to claim 1.

16. A method for manufacturing a display panel, comprising:
arranging a first electrode material layer on a base plate and patterning the first electrode material layer to form a first electrode layer comprising a plurality of first electrodes arranged at intervals;
arranging an electrically conductive functional material layer on the base plate and patterning the electrically conductive functional material layer to obtain a light-transmitting electrically conductive layer comprising a light-transmitting electrically conductive portion;
arranging a pixel defining material layer on the base plate;
preparing an isolation structure at a side of the pixel defining material layer away from the base plate, an isolation opening and a light-transmitting opening being surrounded by the isolation structure, an orthographic projection of the light-transmitting opening on the base plate at least partially overlapping an orthographic projection of the light-transmitting electrically conductive portion on the base plate; and
patterning the pixel defining material layer exposed by the isolation opening to obtain a first opening.

17. The method according to claim 16, wherein in the patterning the pixel defining material layer exposed by the isolation opening to obtain the first opening, retaining a portion of the pixel defining material layer located at a side of the light-transmitting electrically conductive portion away from the base plate to form a second protection portion, or removing the portion of the pixel defining material layer located at the side of the light-transmitting electrically conductive portion away from the base plate to form a second opening.

18. The method according to claim 16, wherein in the arranging the pixel defining material layer on the base plate, patterning the pixel defining material layer to obtain a first connecting hole, a portion of the light-transmitting electrically conductive portion is exposed by the first connecting hole;
in the preparing the isolation structure at the side of the pixel defining material layer away from the base plate, the isolation structure is connected with the light-transmitting electrically conductive portion through the first connecting hole.

19. The method according to claim 16, wherein the display panel further comprises a first power supply signal line located within the base plate or at one side of the base plate, in the arranging the pixel defining material layer on the base plate, patterning the pixel defining material layer to further obtain a second first connecting hole, the first power supply signal line is exposed by the second connecting hole,
in the preparing the isolation structure at the side of the pixel defining material layer away from the base plate, the isolation structure is connected with the first power supply signal line through the second connecting hole.

20. The method according to claim 16, wherein in the arranging the electrically conductive functional material layer on the base plate and patterning the electrically conductive functional material layer to obtain the light-transmitting electrically conductive layer, the light-transmitting electrically conductive layer further comprises a first protection portion spaced apart from the light-transmitting electrically conductive portion and covering at least a portion of the first electrode;
in the patterning the pixel defining material layer exposed by the isolation opening to obtain the first opening: at least a portion of the first protection portion is exposed by the first opening.
